(19) United States
(12) Patent Application Publication
(10) Pub. No.: US 2026/0130074 A1
(43) Pub. Date: May 7, 2026

(54) ELECTRONIC DEVICE INCLUDING DISPLAY DEVICE AND METHOD OF MANUFACTURING ELECTRONIC DEVICE

(71) Applicant: Samsung Display Co., LTD., Yongin-si (KR)

(72) Inventors: YOUNGGON KIM, Yongin-si (KR); JOO YOUNG PARK, Yongin-si (KR); JE YOON YOO, Yongin-si (KR); TAEHYUN JUNG, Yongin-si (KR)

(21) Appl. No.: 19/377,538

(22) Filed: Nov. 3, 2025

(30) Foreign Application Priority Data
Nov. 4, 2024 (KR) 10-2024-0154295

(51) Int. Cl. H10K 59/131; H05K 1/18; H10K 59/12; H10K 59/88; H10K 71/70; H10K 102/00

(52) U.S. Cl. CPC H10K 59/131; H05K 1/189; H10K 59/1201; H10K 59/88; H10K 71/70; H05K 2201/10128; H10K 2102/311

(57) ABSTRACT

A display device includes: a display panel including a display area, a pad area located at one side of the display area, and a bending area between the display area and the pad area; a panel protection film attached to a lower portion of the display panel; a flexible circuit board attached to the pad area; and a cover film attached to the pad area and the flexible circuit board, where the pad area overlaps the display area due to bending of the bending area, and a surface of the cover film, a surface of the display panel, and a surface of the panel protection film are on a same cut surface.

This application claims priority to Korean Patent Application No. 10-2024-0154295, filed on Nov. 4, 2024, and all the benefits accruing therefrom under 35 U.S.C. § 119, the content of which in its entirety is herein incorporated by reference.

### BACKGROUND

### 1. Field

The present disclosure relates to an electronic device including a display device and a method of manufacturing the electronic device.

### 2. Description of the Related Art

Recently, various lightweight and compact flat panel display devices are being developed. Examples of the flat panel display devices include liquid crystal displays (LCDs), field emission displays (FEDs), plasma display panels (PDPs), and organic light-emitting displays (OLEDs).

Among the flat panel display devices, organic light-emitting display devices (OLEDs) display images using an organic light-emitting diode that emits light through the recombination of electrons and holes. These OLEDs are receiving attention as the next-generation displays because OLEDs typically have fast response speeds and operate with low power consumption.

### SUMMARY

Embodiments of the present disclosure provide an electronic device including a display device with improved waterproof performance and attachment quality, and a method of manufacturing the electronic device.

However, the technical objectives to be solved by the present disclosure are not limited to the objectives described above, and other objectives not mentioned may be clearly understood by those skilled in the art from the description of the present disclosure described below.

According to an embodiment of the present disclosure, an electronic device includes a display device including: a display panel including a display area, a pad area located at one side of the display area, and a bending area between the display area and the pad area; a panel protection film attached to a lower portion of the display panel; a flexible circuit board attached to the pad area; and a cover film attached to the pad area and the flexible circuit board, where the pad area overlaps the display area in a state where the bending area is bent, and a side surface of the cover film, a side surface of the display panel, and a side surface of the panel protection film are on a same cut surface.

In an embodiment, the cover film may include at least one selected from an insulation film, a conductive film, or a step film.

In an embodiment, the cut surface may be located at sides of the pad area.

In an embodiment, the pad area includes a marker, and the cover film may expose the marker.

In an embodiment, an inspection wire may be positioned in the pad area, and a distance between the inspection wire and the cut surface may be in a range of about 80 micrometers (μm) to about 150 μm.

In an embodiment, the electronic device may further include a cover layer positioned below the panel protection film.

In an embodiment, the cover layer may include at least one selected from a cushion layer and a metal plate.

In an embodiment, the metal plate may include a material having an elastic modulus of 60 gigapascals (GPa) or greater at a room temperature.

In an embodiment, the electronic device may further include an upper protective film attached to an upper portion of the display panel.

In an embodiment, the display panel may include an organic light-emitting diode.

According to another embodiment of the present disclosure, a method of manufacturing an electronic device including a display device includes: performing a preparation operation of preparing a display panel including a display area, a pad area, and a bending area between the display area and the pad area; performing a panel protection film attachment operation of attaching a panel protection film to a lower surface of the display panel; performing a flexible circuit board attachment operation of attaching a flexible circuit board to the pad area; performing a cover film attachment operation of attaching a cover film to the pad area and the flexible circuit board; performing a cutting operation of simultaneously cutting the cover film, the display panel and the panel protection film; and performing a bending operation of bending the display panel, where a side surface of the cover film, a side surface of the display panel, and a side surface of the panel protection film are on a same cut surface.

In an embodiment, in the performing the cover film attachment operation, the cover film having a greater width than a width of the pad area may be attached.

In an embodiment, a difference in length between one end of the cover film and one end of the pad area may be in a range of about 200 μm to about 500 μm.

In an embodiment, in the performing the cutting operation, the cutting may include laser cutting.

In an embodiment, the method may further include, after the performing the cutting operation, attaching an upper protective film on the display panel.

In an embodiment, the method may further include, after the performing the cutting operation, forming a cover layer below the panel protection film.

In an embodiment, the cover film may include at least one selected from an insulation film, a conductive film, or a step film.

In an embodiment, an inspection wire is positioned in the pad area, and a distance between the inspection wire and the cut surface may be in a range of about 80 μm to about 150 μm.

In an embodiment, the pad area may include a marker, and the cover film may expose the marker.

According to another embodiment of the present disclosure, an electronic device includes: a memory which stores a program; a processor which operates by executing the e program; a display device which receives data from the processor and provides visual information; and a power module which supplies power to the display device, where the display device includes: a display panel including a display area, a pad area located at one side of the display area, and a bending area between the display area and the pad area; a panel protection film attached to a lower portion of the display panel; a flexible circuit board attached to the pad area; and a cover film attached to the pad area and the flexible circuit board, where a side surface of the cover film, a side surface of the display panel, and a side surface of the panel protection film are on a same cut surface.

### BRIEF DESCRIPTION OF THE DRAWINGS

The above and other features of embodiments of the invention will become more apparent by describing in further detail embodiments thereof with reference to the accompanying drawings, in which:

FIG. 1 is a plan view schematically illustrating an example of a display device according to an embodiment of the present disclosure;

FIG. 2 is a perspective view schematically illustrating the display device of FIG. 1 in a bend shape;

FIG. 3 is a cross-sectional view schematically illustrating an example of cross-section A-A′ of FIG. 1;

FIG. 4 is a circuit diagram illustrating an example of an equivalent circuit of one (sub)pixel of the display device of FIG. 1;

FIG. 5 is a cross-sectional view schematically illustrating an example of cross-section C-C′ of FIG. 2;

FIG. 6 is a cross-sectional view schematically illustrating the display device according to FIG. 5 in a state before bending thereof;

FIG. 7 is a flowchart schematically illustrating an example of a method of manufacturing a display device, according to an embodiment of the present disclosure;

FIG. 8 is a plan view schematically illustrating an example of a cover film attached to a display panel and a laser full cut (LFC) cutting line;

FIG. 9 is a photographic image of a cover film attached to a display panel that has been laser-cut;

FIG. 10 is a cross-sectional view schematically illustrating an example of cross-section B-B′ of FIG. 8;

FIG. 11 is a photographic image schematically showing an example of cross-section B-B′ of FIG. 8;

FIG. 12 is a cross-sectional view schematically illustrating an example of a cover film;

FIG. 13 is a cross-sectional view schematically illustrating an example of a waterproof tape and a resin-filled area attached to a display device manufactured according to an embodiment of the present disclosure;

FIG. 14 is a plan view schematically illustrating another example of a display device according to an embodiment of the present disclosure;

FIG. 15 is a block diagram schematically illustrating an example of an electronic device according to embodiments of the present disclosure; and

FIG. 16 is a perspective view schematically illustrating an example of an electronic device including a display device, according to embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the embodiments below, when a part such as a unit, region, or component is described as being located above or on another part, this includes not only the case where the part is directly above the other part, but also the case where another unit, region, component, etc. is interposed in between.

In the embodiments below, terms such as “connect” or “combine” do not necessarily imply a direct and/or fixed connection or combination of two members, unless the context clearly indicates otherwise, and do not exclude the presence of another member between the two members.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Also, in the drawings, for convenience of description, sizes of elements may be exaggerated or contracted. For example, the size and/or thickness of each component shown in the drawings are arbitrarily shown for convenience of description, and therefore the present disclosure is not necessarily limited to the drawings.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings. When describing with reference to the drawings, identical or corresponding components are given the same drawing reference numerals and any repetitive detailed descriptions thereof will be omitted or simplified.

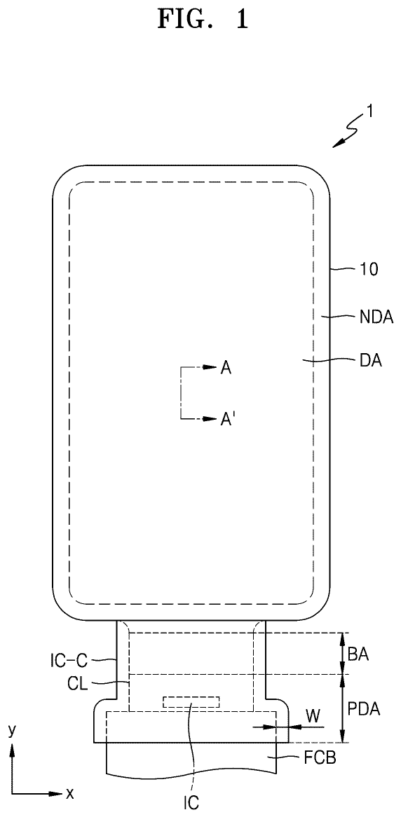

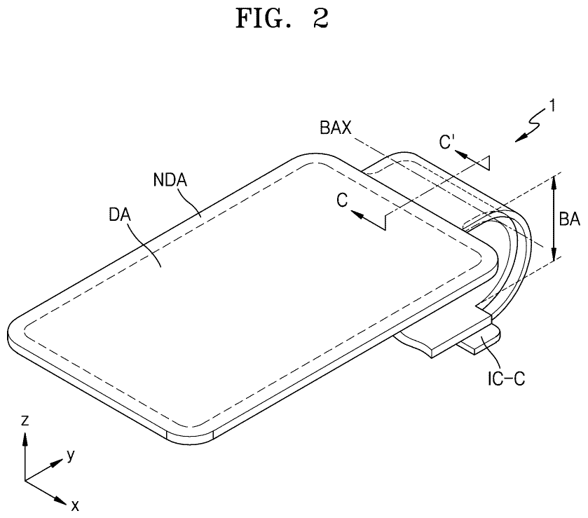

FIG. 1 is a plan view schematically illustrating an example of a display device according to an embodiment of the present disclosure, and FIG. 2 is a perspective view schematically illustrating the display device of FIG. 1 in a bent shape.

Referring to FIGS. 1 and 2, an embodiment of a display device 1 may be a device that displays a moving image or still image, and may provide a screen on a display panel 10 or perform input and output of data. The display device 1 may be used to provide a display screen of various electronic devices such as a mobile phone, a smart phone, a tablet personal computer, a mobile communication terminal, an electronic notebook, an electronic book, a portable multimedia player (PMP), a navigation device, an ultra-mobile PC (UMPC), etc., as well as a television, a laptop, a monitor, a billboard, an Internet of Things (IOT) device, etc. In addition, the display device 1 according to an embodiment may be used in electronic devices such as wearable devices, such as a smart watch, a watch phone, a glasses-type display, and a head mounted display (HMD). In addition, the display device 1 according to an embodiment may be used as a display of various electronic devices, for example, a dashboard of an automobile, a Center Information Display (CID) arranged on a center fascia or dashboard of an automobile, a room mirror display replacing a side mirror of an automobile, and a display arranged on the back of a front seat as entertainment for the rear seats of an automobile.

The display device 1 according to an embodiment of the present disclosure may include a display area DA in which a plurality of pixels are positioned, and a non-display area NDA outside the display area DA. In addition, the non-display area NDA may include a pad area PDA which is located at one side of the display area DA and is an area to which various electronic components such as an integrated circuit IC or a flexible circuit board FCB are electrically attached, and a bending area BA between the display area DA and the pad area PDA. The display area DA, the non-display area NDA, the pad area PDA, and the bending area BA may be defined on a substrate.

FIG. 1 is a plan view illustrating a shape of a substrate, etc. during a manufacturing process of the display device 1, and the substrate, etc. may have the bending area BA bendable based on a bending axis BAX extending in a first direction (x), as illustrated in FIG. 2. Here, a bending direction is set such that the pad area PDA is located at the back of the display area DA in a bent state. Accordingly, the area of the non-display area NDA perceived by a user may be minimized.

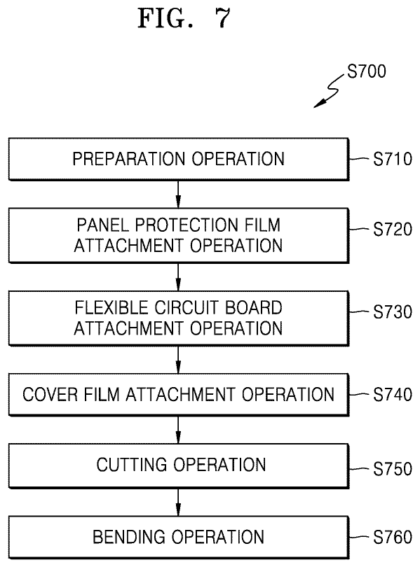

A cover film IC-C may be attached to the pad area PDA. The cover film IC-C may be attached to the flexible circuit board FCB which may be positioned in pad area PDA. The cover film IC-C may protect the pad area PDA and the flexible circuit board FCB from mechanical impact and add waterproofing and insulation performance to the pad area PDA and the flexible circuit board FCB. This will be described in detail later with reference to FIGS. 7 to 11.

FIG. 1 illustrates the cover film IC-C attached to the pad area PDA and the flexible circuit board FCB before performing a laser full cut (LFC) process described later during a manufacturing process of the display device 1 according to an embodiment of the present disclosure.

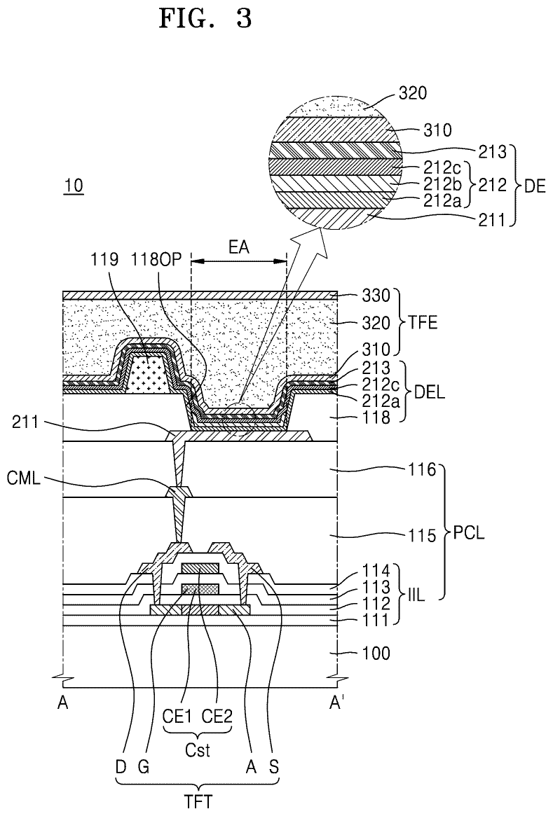

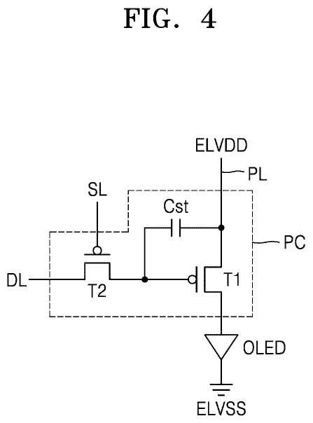

FIG. 3 is a cross-sectional view schematically illustrating an example of a cross-section taken along cross-section A-A′ of FIG. 1, and FIG. 4 is a circuit diagram illustrating an example of an equivalent circuit of one (sub)pixel of the display device 1 of FIG. 1.

Referring to FIG. 3, an embodiment of the display device 1 may include the display panel 10. In such an embodiment, the display panel 10 may include a substrate 100, a buffer layer 111, a pixel circuit layer PCL, a display element layer DEL, and a thin-film encapsulation layer TFE.

The substrate 100 may include a transparent glass material including SiO₂ as its main component. However, the present disclosure is not limited thereto, and the substrate 100 may include a transparent plastic material. The plastic material may include polyethersulfone (PES), polyacrylate (PAR), polyetherimide (PEI), polyethylene naphthenate (PEN), polyethylene terephthalate (PET), polyphenylene sulfide (PPS), polyarylate, polyimide, polycarbonate, cellulose triacetate (TAC), cellulose acetate propionate (CAP), etc. In an embodiment, the substrate 100 may have a multilayer structure including a base layer including the polymer resin described above and a barrier layer (not shown). The substrate 100 including a polymer resin may be flexible, rollable, or bendable.

The buffer layer 111 may be arranged (disposed or formed) on the substrate 100. The buffer layer 111 may include an inorganic insulation material such as silicon nitride, silicon oxynitride, and silicon oxide, and may be provided as a single layer or multiple layers including the inorganic insulation material described above.

The pixel circuit layer PCL may be arranged on the buffer layer 111. The pixel circuit layer PCL may include a thin-film transistor TFT included in a pixel circuit and an inorganic insulating layer IIL, a first planarization layer 115, and a second planarization layer 116 arranged under and/or over components of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. Alternatively, the semiconductor layer A may include at least one selected from amorphous silicon, an oxide semiconductor, and an organic semiconductor, etc. The semiconductor layer A may include a channel region and a drain region and a source region respectively arranged on opposite sides of the channel region. The gate electrode G may overlap the channel region in a thickness direction of the substrate 100.

The gate electrode G may include a low-resistance metal material. The gate electrode G may include a conductive material including at least one selected from molybdenum (Mo), aluminum (Al), copper (Cu), titanium (Ti), etc., and may be formed as a multilayer or a single layer including at least one selected from the above materials.

The first gate insulating layer 112 between the semiconductor layer A and the gate electrode G may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may be provided to cover the gate electrode G. The second gate insulating layer 113 may, similarly to the first gate insulating layer 112, include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may include zinc oxide (ZnO) and/or zinc peroxide (ZnO₂).

An upper electrode CE2 of a storage capacitor Cst may be arranged on the second gate insulating layer 113. The upper electrode CE2 may overlap the gate electrode G therebelow in the thickness direction of the substrate 100. The gate electrode G and the upper electrode CE2 overlapping each other with the second gate insulating layer 113 therebetween may form the storage capacitor Cst of the pixel circuit. That is, the gate electrode G may function as a lower electrode CE1 of the storage capacitor Cst. As above, the storage capacitor Cst and the thin-film transistor TFT may overlap each other in the thickness direction of the substrate 100. However, the present disclosure is not limited thereto, and in some embodiments, the storage capacitor Cst may be formed not to overlap the thin-film transistor TFT in the thickness direction of the substrate 100.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of at least one selected from the materials described above.

The interlayer insulating layer 114 may cover the upper electrode CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The interlayer insulating layer 114 may be a single layer or multiple layers including at least one selected from the inorganic insulating material described above.

A drain electrode D and a source electrode S may be each positioned on the interlayer insulating layer 114. The drain electrode D and the source electrode S may include a material having high conductivity. The drain electrode D and the source electrode S may include a conductive material including molybdenum (Mo), aluminum (Al), copper (Cu), titanium (Ti), etc., and may be formed as a multilayer or single layer including at least one selected from the above materials. In an embodiment, for example, the drain electrode D and the source electrode S may have a multilayer structure of Ti/Al/Ti.

The first planarization layer 115 may be arranged to cover the drain electrode D and the source electrode S. The first planarization layer 115 may include an organic insulating layer. The first planarization layer 115 may include an organic insulator such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, or a blend thereof.

A connection electrode CML may be arranged on the first planarization layer 115. Here, the connection electrode CML may be connected to the drain electrode D or the source electrode S through a contact hole of the first planarization layer 115. The connection electrode CML may include a material with high conductivity. The connection electrode CML may include a conductive material including molybdenum (Mo), aluminum (Al), copper (Cu), titanium (Ti), etc., and may be formed as a multilayer or single layer including at least one selected from the above materials. In an embodiment, for example, the connection electrode CML may have a multilayer structure of Ti/Al/Ti.

The second planarization layer 116 may be arranged to cover the connection electrode CML. The second planarization layer 116 may include an organic insulating layer. The second planarization layer 116 may include an organic insulator such as a general-purpose polymer such as PMMA or PS, a polymer derivative having a phenol group, an acrylic polymer, an imide polymer, an aryl ether polymer, an amide polymer, a fluorinated polymer, a p-xylene polymer, a vinyl alcohol polymer, or a blend thereof.

The display element layer DEL may be arranged on the pixel circuit layer PCL. The display element layer DEL may include a display element DE. The display element DE may be an organic light-emitting diode (OLED). A pixel electrode 211 of the display element DE may be electrically connected to the connection electrode CML through a contact hole of the second planarization layer 116.

The pixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 211 may further include a film including ITO, IZO, ZnO or In₂O₃ above/below the reflective film.

A pixel-defining layer 118 provided with (or defining) an opening 118OP exposing a central portion of the pixel electrode 211 may be arranged on the pixel electrode 211. The pixel-defining layer 118 may include an organic insulating material and/or an inorganic insulating material. The opening 118OP may define an emission area EA of light emitted from the display element DE (hereinafter referred to as ‘emission area’). In an embodiment, for example, a width of the opening 118OP may correspond to a width of the emission area EA of the display element DE.

In an embodiment, the pixel-defining layer 118 may include a light-blocking material and include black. The light-blocking material may include carbon black, carbon nanotubes, a resin or paste containing black dye, metal particles such as nickel, aluminum, molybdenum and alloys thereof, metal oxide particles (e.g., chromium oxide), or metal nitride particles (e.g., chromium nitride). In an embodiment where the pixel-defining layer 118 includes a light-blocking material, external light reflection by metal structures arranged under the pixel-defining layer 118 may be reduced.

A spacer 119 may be arranged on the pixel-defining layer 118. The spacer 119 may be used to effectively prevent damage to the substrate 100 in a method of manufacturing a display device. When manufacturing the display panel 10, a mask sheet may be used. When the mask sheet enters the opening 118OP of the pixel-defining layer 118 or is in close contact with the pixel-defining layer 118 to deposit a deposition material on the substrate 100, a defect in which a portion of the substrate 100 is damaged or broken by the mask sheet may be effectively prevented by the spacer 119.

The spacer 119 may include an organic insulating material such as polyimide. Alternatively, the spacer 119 may include an inorganic insulator such as silicon nitride or silicon oxide, or may include an organic insulator.

In an embodiment, the spacer 119 may include a material different from that of the pixel-defining layer 118. Alternatively, in another embodiment, the spacer 119 may include a same material as the pixel-defining layer 118, and the pixel-defining layer 118 and the spacer 119 may be formed together in a mask process using a halftone mask or the like.

An intermediate layer 212 may be arranged on the pixel-defining layer 118. The intermediate layer 212 may include an emission layer 212b arranged in the opening 118OP of the pixel-defining layer 118. The emission layer 212b may include a polymer or low-molecular organic material that emits light of a certain color.

A first functional layer 212a and a second functional layer 212c may be arranged on and under the emission layer 212b, respectively. The first functional layer 212a may include, for example, a hole transport layer (HTL) or a hole transport layer and a hole injection layer (HIL). The second functional layer 212c is a component positioned on the emission layer 212b and may be optional. The second functional layer 212c may include an electron transport layer (ETL) and/or an electron injection layer (EIL). The first functional layer 212a and/or the second functional layer 212c may be a common layer formed to cover the entire substrate 100, similar to an opposite electrode 213 described later.

The opposite electrode 213 may include a conductive material with a low work function. In an embodiment, for example, the opposite electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 213 may further include a layer such as ITO, IZO, ZnO or In₂O₃ on the (semi)transparent layer including the material described above.

In some embodiments, a capping layer (not shown) may be further disposed on the opposite electrode 213. The capping layer may include LiF, an inorganic material, and/or an organic material.

The thin-film encapsulation layer TFE may be arranged on the opposite electrode 213. In an embodiment, the thin-film encapsulation layer TFE may include at least one inorganic encapsulation layer and at least one organic encapsulation layer. In an embodiment, for example, the thin-film encapsulation layer TFE may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may each include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acrylic resin, an epoxy-based resin, polyimide, polyethylene, or the like. In an embodiment, the organic encapsulation layer 320 may include acrylate.

FIG. 4 is an equivalent circuit diagram schematically illustrating a pixel circuit PC that may be applied to a display panel.

Referring to FIG. 4, in an embodiment, the pixel circuit PC may be connected to a display element, for example, an organic light-emitting diode OLED. The pixel circuit PC may include a driving thin-film transistor T1, a switching thin-film transistor T2, and a storage capacitor Cst. Additionally, the organic light-emitting diode OLED may emit red, green, or blue light, or may emit red, green, blue, or white light.

The switching thin-film transistor T2 may be connected to a scan line SL and a data line DL, and may be configured to transmit a data signal or data voltage input from the data line DL to the driving thin-film transistor T1, based on a scan signal or switching voltage input from the scan line SL. The storage capacitor Cst may be connected to the switching thin-film transistor T2 and a driving voltage line PL, and may store a voltage corresponding to a difference between a voltage received from the switching thin-film transistor T2 and a first power voltage ELVDD supplied to the driving voltage line PL.

The driving thin-film transistor T1 may be connected to the driving voltage line PL and the storage capacitor Cst, and may control, in response to a voltage value stored in the storage capacitor Cst, a driving current flowing from the driving voltage line PL and through the organic light-emitting diode OLED. The organic light-emitting diode OLED may emit light having a certain luminance, according to the driving current. An opposite electrode of the organic light-emitting diode OLED may be supplied with a second power supply voltage ELVSS.

Although FIG. 4 illustrates an embodiment where the pixel circuit PC includes two thin-film transistors and one storage capacitor, the pixel circuit PC may include three, four, five or more thin-film transistors in another embodiment.

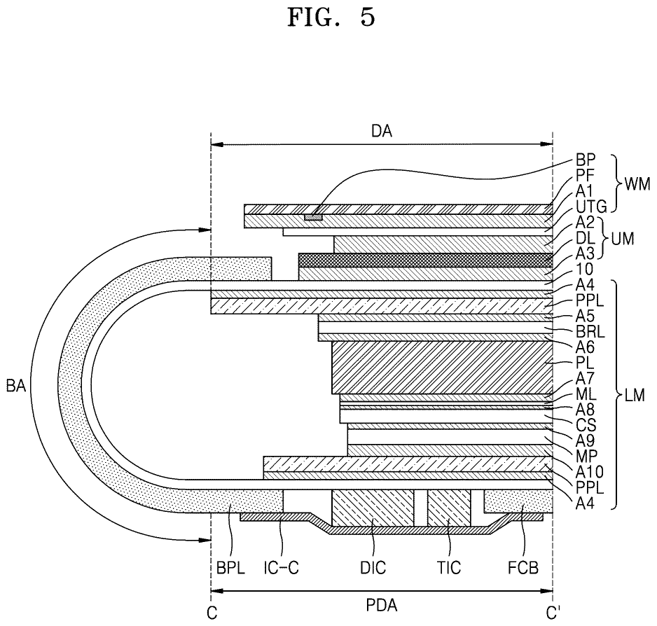

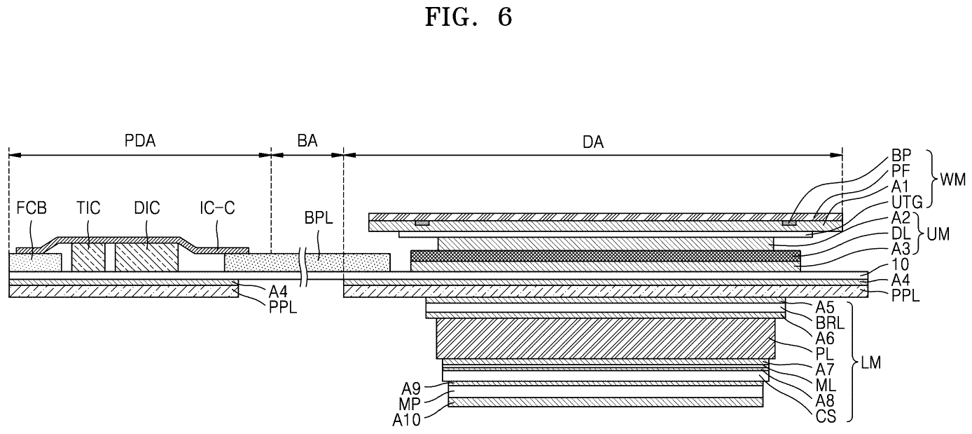

FIG. 5 is a cross-sectional view schematically illustrating an example of cross-section C-C′ of FIG. 2, and FIG. 6 is a cross-sectional view schematically illustrating a display device according to FIG. 5 in a state before bending thereof.

Referring to FIGS. 5 and 6, a display device according to an embodiment of the present disclosure may include a window WM, an upper member UM, the display panel 10, and a lower member LM. The upper member UM generally refers to a configuration positioned between the window WM and the display panel 10, and the lower member LM generally refers to a configuration below the display panel 10.

The window WM may include a thin-film glass substrate UTG, a window protection layer PF disposed on the thin-film glass substrate UTG, and a bezel pattern BP disposed on a lower surface of the window protection layer PF. In an embodiment, the window protection layer PF may include a synthetic resin film. In an embodiment, a functional layer (not shown) may be further disposed on the window protection layer PF. The functional layer may include at least one selected from a hard coating layer, an anti-fingerprint layer, and an anti-reflection layer.

The bezel pattern BP may be arranged on one surface of the thin-film glass substrate UTG or one surface of the window protection layer PF. FIGS. 5 and 6 illustrate an embodiment where the bezel pattern BP is disposed on the lower surface of the window protection layer PF, but the present disclosure is not limited thereto, and the bezel pattern BP may be disposed on an upper surface of the window protection layer PF in another embodiment. The bezel pattern BP may be a colored shading film. In an embodiment, for example, the bezel pattern BP may be formed by a coating method. The bezel pattern BP may include a base material and a dye or pigment mixed into the base material. The non-display area NDA illustrated in FIG. 1 may be defined by a shape of the bezel pattern BP.

A thickness of the thin-film glass substrate UTG may be, for example, in a range of about 15 micrometers (μm) to about 45 μm. Additionally, the thin-film glass substrate UTG may be chemically strengthened glass. Accordingly, the thin-film glass substrate UTG may minimize wrinkles even when folding and unfolding operations thereof are repeated.

A thickness of the window protection layer PF may be, for example, in a range about 50 μm to about 80 μm. The synthetic resin film of the window protection layer PF may include at least one selected from polyimide, polycarbonate, polyamide, triacetylcellulose, polymethylmethacrylate, or polyethylene terephthalate.

The window protection layer PF and the thin-film glass substrate UTG may be bonded by a first adhesive layer A1. The first adhesive layer A1 may be a pressure sensitive adhesive film (PSA) or an optically clear adhesive (OCA). Adhesive layers A2 to A10 described below may also include a same adhesive as the first adhesive layer A1.

The first adhesive layer A1 may be separated from the thin-film glass substrate UTG. That is, the adhesive force between the first adhesive layer A1 and the thin-film glass substrate UTG may be less than the adhesive force between the first adhesive layer A1 and the window protection layer PF. In an embodiment where the window protection layer PF is arranged on top of the thin-film glass substrate UTG, scratches may occur relatively easily compared to the thin-film glass substrate UTG. In such an embodiment, after separating the first adhesive layer A1 from the window protection layer PF, a new window protection layer PF may be attached to the thin-film glass substrate UTG.

The upper member UM may include an upper protective film DL. The upper protective film DL may include a synthetic resin film. The synthetic resin film may include at least one selected from polyimide, polycarbonate, polyamide, triacetylcellulose, polymethylmethacrylate, or polyethylene terephthalate.

The upper protective film DL may absorb external impact applied to the front of the display panel 10. The thin-film glass substrate UTG and the upper protective film DL may be bonded to each other by a second adhesive layer A2. Additionally, the upper protective film DL and the display panel 10 may be coupled to each other by a third adhesive layer A3.

The lower member LM may include a panel protection film PPL, a barrier layer BRL, a lower plate PL, a metal layer ML, a cushion layer CS, and a metal plate MP.

The panel protection film PPL may be arranged below the display panel 10. The panel protection film PPL may protect a lower portion of the display panel 10. The panel protection film PPL may include, for example, a flexible synthetic resin film.

In an embodiment, the panel protection film PPL may include a base film and a shielding portion. The base film may include at least one selected from polyurethane and polyimide. In an embodiment, the shielding portion may include magnetic metal powder (MMP). Accordingly, the panel protection film PPL may have an electromagnetic shielding function. The shielding portion may be arranged on an upper surface of the panel protection film PPL adjacent to the display panel 10, or magnetic metal powder may be arranged inside the panel protection film PPL.

The panel protection film PPL may not be arranged in the bending area BA. In an embodiment, for example, the panel protection film PPL may not be arranged in the bending area BA, but may be arranged in the display area DA and the pad area PDA. A fourth adhesive layer A4 may bind the panel protection film PPL to the display panel 10.

In an embodiment, as illustrated in FIG. 2, the bending area BA may be bent based on an imaginary bending axis BAX extending in the first direction (x). In a state where the bending area BA is bent, the panel protection film PPL arranged in the pad area PDA may be arranged below the panel protection film PPL arranged in the display area DA.

In an embodiment, since the panel protection film PPL is not arranged in the bending area BA, the bending area BA may be bent easily. Here, the panel protection film PPL arranged in the pad area PDA may be attached to the metal plate MP through a tenth adhesive layer A10.

The bending area BA has a predetermined curvature and radius of curvature in the bent state. Here, the radius of curvature may be in a range of about 0.1 millimeter (mm) to about 0.5 mm. A bending protection layer BPL may be disposed in the bending area BA, a portion of the display area DA, and a portion of the pad area PDA. That is, referring to FIG. 6, the bending protection layer BPL may be disposed over the entire area of the bending area BA, and may be disposed over a portion of the display area DA and a portion of the pad area PDA.

The bending protection layer BPL may be bent together with the bending area BA. The bending protection layer BPL may protect the bending area BA from external impact and control a neutral plane of the bending area BA.

When the bending area BA is bent, a first driving chip DIC, a second driving chip TIC, and the flexible circuit board FCB arranged in the pad area PDA may overlap a back surface of the display panel 10, which overlaps the display area DA.

In an embodiment, the cover film IC-C may be attached to the pad area PDA, the first driving chip DIC, the second driving chip TIC, and the flexible circuit board FCB. That is, the cover film IC-C may be arranged at an end of the bending protection layer BPL to cover the first driving chip DIC, the second driving chip TIC, and the flexible circuit board FCB.

The barrier layer BRL may be arranged below the panel protection film PPL. The barrier layer BRL and the panel protection film PPL may be coupled to each other through a fifth adhesive layer A5. The barrier layer BRL may increase resistance to compressive force due to external pressure. Therefore, the barrier layer BRL may prevent deformation of the display panel 10.

The barrier layer BRL may include a flexible plastic material such as polyimide, polycarbonate, polyamide, triacetylcellulose, polymethylmethacrylate, or polyethylene terephthalate.

In an embodiment, the barrier layer BRL may include a colored film having low light transmittance. In such an embodiment, the barrier layer BRL may absorb light incident from the outside. In an embodiment, for example, the barrier layer BRL may include a black synthetic resin film. As a result, when viewing the display panel 10 from the upper side of the window protection layer PF, components arranged below the barrier layer BRL may not be visible to the user.

A sixth adhesive layer A6 may couple the barrier layer BRL to the lower plate PL supporting the display panel 10. The lower plate PL may include, for example, stainless steel. In another embodiment, the lower plate PL may be omitted.

A seventh adhesive layer A7 may couple the lower plate PL to the metal layer ML. The metal layer ML may be arranged below the lower plate PL. The metal layer ML may emit heat generated during operation of the display panel 10, to the outside. The metal layer ML may transfer heat generated in the display panel 10 downward. The metal layer ML may have greater electrical conductivity and thermal conductivity than the metal plate MP described below. In an embodiment, for example, the metal layer ML may include at least one selected from copper or aluminum.

A cover layer may be arranged below the metal layer ML. The cover layer may include at least one selected from the cushion layer CS that absorbs external impact and prevents damage to the display panel 10, and the metal plate MP that supports the display panel 10.

An eighth adhesive layer A8 may couple the metal layer ML to the cushion layer CS. The cushion layer CS may protect the display panel 10 from impact transmitted from below the display panel 10. In an embodiment, for example, the cushion layer CS may include foam or sponge. The foam may include polyurethane foam or thermoplastic polyurethane foam. In an embodiment where the cushion layer CS includes a foam, a barrier film may be added as a base layer to the cushion layer CS, and a foaming agent may be foamed onto the barrier film to form the cushion layer CS.

A ninth adhesive layer A9 may couple the cushion layer CS to the metal plate MP. The metal plate MP may absorb external impact applied from below the display panel 10 and support the display panel 10. The metal plate MP may have greater strength and greater thickness than the metal layer ML.

The metal plate MP may include a material having an elastic modulus of about 60 gigapascals (GPa) or more at a room temperature (e.g., 15° to 25° C.). The metal plate MP may include a single metal material or an alloy of multiple metal materials and thus improve the heat dissipation performance of an electronic device including a display device. In an embodiment, for example, the metal plate MP may be SUS304, but is not limited thereto and the metal plate MP may include various metal materials. In an embodiment, a heat dissipation layer may be arranged below the metal plate MP.

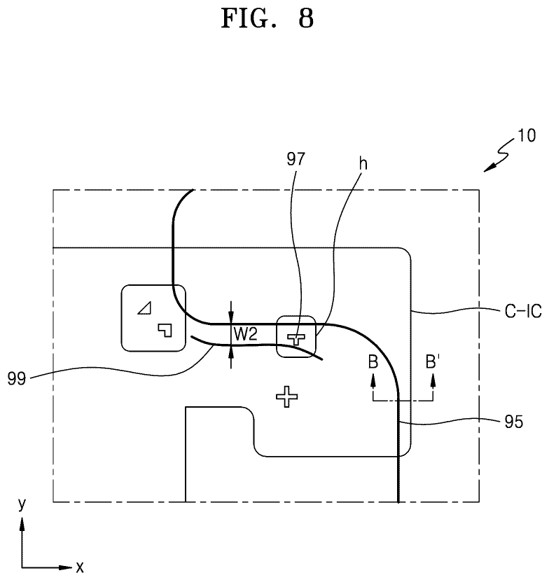

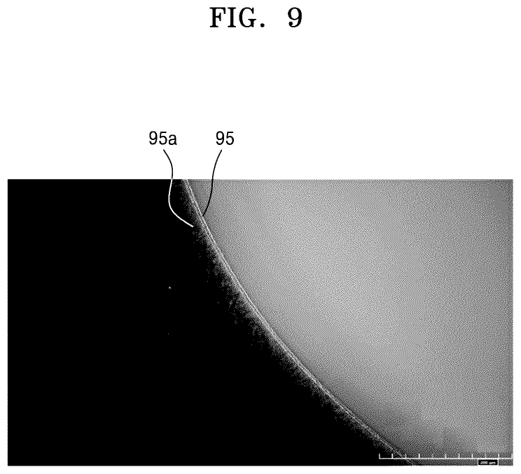

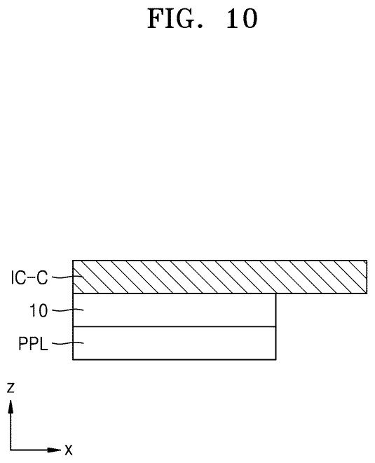

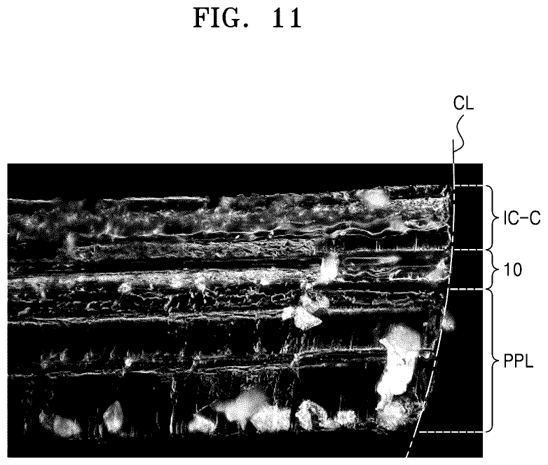

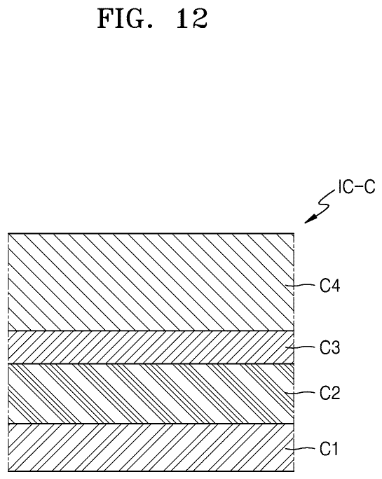

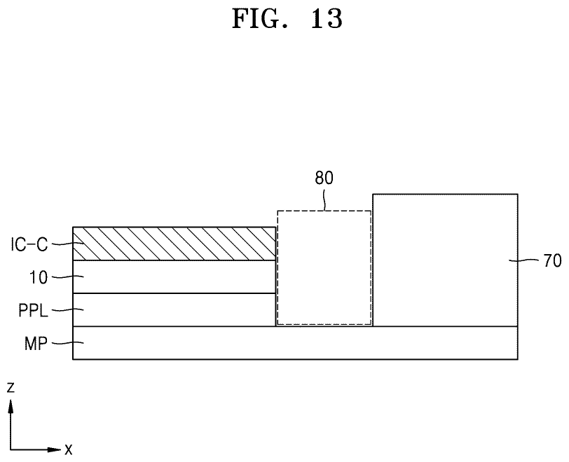

FIG. 7 is a flowchart schematically illustrating an example of a method of manufacturing a display device, according to an embodiment of the present disclosure. FIG. 8 is a plan view schematically illustrating an example of a cover film attached to a display panel and an LFC cutting line. FIG. 9 is a photographic image illustrating a cover film attached to a display panel after being laser-cut. FIG. 10 is a cross-sectional view schematically illustrating an example of cross-section B-B′ of FIG. 8. FIG. 11 is a photographic image schematically illustrating an example of cross-section B-B′ of FIG. 8. FIG. 12 is a cross-sectional view schematically illustrating an example of a cover film. FIG. 13 is a cross-sectional view schematically illustrating an example of a waterproof tape and a resin filling area attached to a display device manufactured according to an embodiment of the present disclosure.

Referring to FIGS. 7 to 13 together with FIGS. 5 and 6, a method S700 of manufacturing a display device according to an embodiment of the present disclosure may include performing a preparation operation S710 of preparing a display panel including a display area, a pad area, and a bending area between the display area and the pad area, performing a panel protection film attachment operation S720 of attaching a panel protection film to a lower surface of the display panel, performing a flexible circuit board attachment operation S730 of attaching a flexible circuit board to the pad area, performing a cover film attachment operation S740 of attaching a cover film on the pad area and the flexible circuit board, performing a cutting operation S750 of simultaneously cutting the cover film, the display panel, and the panel protection film, and performing a bending operation S760 of bending the display panel.

The panel protection film PPL may be attached to a bottom surface of the display panel 10. The display panel 10 and the panel protection film PPL may be coupled to each other by the fourth adhesive layer A4.

In an embodiment, the first driving chip DIC, the second driving chip TIC, and the flexible circuit board FCB may be attached to an upper surface of the display panel 10 located in the pad area PDA. Thereafter, the cover film IC-C may be attached to the pad area PDA, the first driving chip DIC, the second driving chip TIC, and the flexible circuit board FCB.

Referring to FIGS. 1, 10, and 11, the cover film IC-C having a greater width than that of the pad area PDA may be attached. A difference W in length between one end of the cover film IC-C and one end of the pad area PDA may be in a range of about 200 μm to about 500 μm. The reason for attaching the cover film IC-C having a greater width than that of the pad area PDA will be described later.

In an embodiment, as shown in FIG. 7, the panel protection film PPL attachment operation S720 of attaching the panel protection film PPL to a lower surface of the display panel 10 is performed prior to the flexible circuit board attachment operation S730 of attaching the first driving chip DIC, the second driving chip TIC, and the flexible circuit board FCB to the pad area PDA, but the order of the manufacturing processes of a display device is not limited thereto. In another embodiment, for example, the flexible circuit board attachment operation S730 of attaching the first driving chip DIC, the second driving chip TIC, and the flexible circuit board FCB to the pad area PDA may be performed first, and then the panel protection film PPL attachment operation S720 of attaching the panel protection film PPL to the lower surface of the display panel 10 may be performed. In another embodiment, for example, the flexible circuit board attachment operation S730 of attaching the first driving chip DIC, the second driving chip TIC, and the flexible circuit board FCB to the pad area PDA and the panel protection film PPL attachment operation S720 of attaching the panel protection film PPL to the lower surface of the display panel 10 may be performed simultaneously.

After attaching the cover film IC-C covering the first driving chip DIC, the second driving chip TIC, and the flexible circuit board FCB which may be positioned in pad area PDA, and attaching the panel protection film PPL to the lower surface of the display panel 10, the cutting operation S750 of simultaneously cutting the cover film IC-C, the display panel 10, and the panel protection film PPL may be performed. The cutting operation may be performed using an LFC.

Accordingly, as illustrated in FIG. 10, the cover film IC-C, the display panel 10, and the panel protection film PPL may have a same cut surface (CL of FIG. 1), that is a cut surface (or a side surface) of the cover film IC-C, a cut surface (or a side surface) of the display panel 10, and a cut surface (or a side surface) of the panel protection film PPL may be on a same cut surface (or collectively define a same cut surface) e.g., a same smooth or substantially continuous surface. Referring again to FIG. 1, the cut surface CL may be formed on respective side ends of the pad area PDA. Here, the cut surface CL may refer to, for example, a surface that is obtained by simultaneously cutting the cover film IC-C and the panel protection film PPL attached to the display panel 10 in the pad area PDA.

When the cover film IC-C, the display panel 10, and the panel protection film PPL are cut to have the same cut surface CL, as shown in FIGS. 10 and 11, one end of each of the cover film IC-C, the display panel 10, and the panel protection film PPL may have a shape without steps.

Referring to FIG. 8, the pad area PDA may include at least one marker 97. In an embodiment where a display device is applied to an electronic device (e.g., a smart phone), the marker 97 may be used to align the display device in proper position in the electronic device. In an embodiment, for example, the marker 97 formed on the display device and another marker formed on the electronic device may be aligned with each other to align the display device in proper position in the electronic device.

When attaching the cover film IC-C having a greater width than that of the pad area PDA and cutting the cover film IC-C, the display panel 10, and the panel protection film PPL along a cutting line 95, the cover film IC-C may include a groove or hole (h) for exposing the marker 97.

In an embodiment, an inspection wire 99 may be located in the pad area PDA. The inspection wire 99 may be referred to as a crack detection wire or a module crack detection (MCD) wire. In case that a defect such as a crack occurs in the display device, the resistance of the inspection wire 99 may change. Accordingly, a crack detection circuit (not shown) that may be connected to the inspection wire 99 may detect a change in the resistance of the inspection wire 99 to inspect for defects such as cracks in the display device.

In the cutting operation S750, the cutting line 95 and the inspection wire 99 located within the pad area PDA may be desired to be separated from each other so that the inspection wire 99 is not damaged during cutting. Therefore, in an embodiment, a distance W2 between the inspection wire 99 and the cutting line 95, which is the cut surface CL, may be in a range of about 80 μm to about 150 μm.

In the related art, when attaching the cover film IC-C on the display panel 10, instead of attaching the cover film IC-C by a width greater than the width of the pad area PDA and then cutting the cover film IC-C and the pad area PDA, the cover film IC-C is attached to an inner portion of the cut pad area PDA. That is, the cover film IC-C is attached to the inner portion of the cutting line 95, and accordingly, a gap between the inspection wire 99 and an edge of the cover film IC-C was also relatively short.

In an embodiment of the present disclosure, when the cover film IC-C having a width greater than that of the pad area PDA is attached and then cut, a gap between the edge of the cover film IC-C and the inspection wire 99 may have a free space of about 280 μm to about 650 μm, so that damage to the inspection wire 99 may be effectively prevented due to tolerance when cutting the display panel 10 and the panel protection film PPL.

In an embodiment, referring to FIG. 9, when the cover film IC-C having a width greater than that of the pad area PDA is attached and then laser-cut along the cutting line 95, a laser processing mark 95a may be formed near the cutting line 95. The laser processing mark 95a may be on a front and/or back surface of the display panel 10 near the cutting line 95.

In an embodiment, after the cutting operation S750, an operation of attaching, on the display panel 10, the upper member UM including the upper protective film DL and the window WM may be performed. Additionally, after the cutting operation S750, an operation of forming the lower member LM including a cover layer under the panel protection film PPL may be performed. However, the order of the operation of attaching the upper member UM and the window WM and the operation of forming the lower member LM may vary depending on the order of the manufacturing processes of the display device.

Thereafter, the bending operation S760 of bending the bending area BA based on the bending axis BAX may be performed.

In an embodiment, the cover film IC-C may include at least one selected from an insulation film, a conductive film, or a step film. Referring to FIG. 12, the cover film IC-C may include, for example, a step film C1, a first insulation film C2 on the step film C1, a conductive film C3 on the first insulation film C2, and a second insulation film C4 on the conductive film C3.

The step film C1 may compensate for steps formed with different widths between components when the cover film IC-C is attached onto the pad area PDA, the first driving chip DIC, the second driving chip TIC, and the flexible circuit board FCB.

The first insulation film C2 may be arranged on the step film C1. According to an embodiment, the first insulation film C2 may include an insulating material. In an embodiment, for example, the first insulation film C2 may include a polymer material, a mesh fabric, or a highly flexible metal material. The polymer material may include at least one selected from polyethylene terephthalate (PET) and foam. Mesh fabrics may have higher moduli than polymeric materials. Polymer materials and metal materials may improve the impact resistance and protective function of the cover film IC-C, and relatively reduce the tensile stress of the cover film IC-C. Accordingly, contents of the materials described above included in the first insulation film C2 may be adjusted considering the characteristics of the cover film IC-C.

The conductive film C3 may be arranged on the first insulation film C2. The conductive film C3 may include a conductive material. In an embodiment, for example, the conductive film C3 may include either a metal material or a conductive fiber. According to an embodiment, the conductive fiber may include a non-woven fabric. In an embodiment, for example, the conductive film C3 may be electrically grounded.

The conductive film C3 may be arranged between the first insulation film C2 and the second insulation film C4 and thus shield electromagnetics. Accordingly, the cover film IC-C may prevent damage to the display panel 10, the first driving chip DIC, the second driving chip TIC, and the flexible circuit board FCB by external static electricity, thereby improving the stability of the electronic device including the display device.

The second insulation film C4 may be arranged on the conductive film C3. The second insulation film C4 may include an insulating material. The second insulation film C4 may include a polymer material or mesh fabric. In an embodiment, for example, the polymer material may include polyethylene terephthalate (PET). According to an embodiment, the second insulation film C4 may be black and may act as a light shield.

The arrangement order of the insulation film, the conductive film, and the step film of the cover film IC-C is not limited to the order shown in FIG. 12. In another embodiment, for example, the cover film IC-C may include a conductive film arranged between insulation films and a step film may be arranged as the uppermost layer thereof. In an embodiment, for example, the cover film IC-C may have a two-layer structure in which a step film is omitted and a conductive film is positioned on an insulation film.

Referring to FIG. 13 together with FIG. 7, after the bending operation S760 of bending the display panel, a waterproof tape 70 may be attached on the metal plate MP. Thereafter, a space 80 between the waterproof tape 70, the cover film IC-C, the display panel 10, and the panel protection film PPL may be filled with resin or the like to seal the display panel 10.

As described above, in the cutting operation S750, the cover film IC-C, the display panel 10, and the panel protection film PPL are cut simultaneously, and thus the cover film IC-C, the display panel 10, and the panel protection film PPL may have a same cut surface (CL in FIG. 1). Accordingly, as illustrated in FIG. 13, the cut surface CL of the cover film IC-C, the display panel 10, and the panel protection film PPL may have a stepless and smooth surface structure. As a result, when filling the space 80 between the waterproof tape 70 and the cover film IC-C, the display panel 10 and the panel protection film PPL, underfilling of the resin may be effectively prevented, thereby sealing the display panel 10 without any gaps, and thus the waterproof performance of the electronic device including the display device may be improved.

As described above, in the related art, when attaching the cover film IC-C on the display panel 10, instead of attaching the cover film IC-C having a greater width than that of the pad area PDA and then cutting the cover film IC-C and the pad area PDA, the cover film IC-C is attached to the inner portion of the pad area PDA that is cut. That is, the cover film IC-C, the display panel 10, and the panel protection film PPL do not have the same cut surface, and there is a step difference in the cut surfaces of the cover film IC-C, the display panel 10, and the panel protection film PPL.

If, as in the related art, the cover film IC-C, the display panel 10, and the panel protection film PPL are not cut simultaneously, and a step (or a stepped structure) may be formed or defined in the cut surface of the cover film IC-C, the display panel 10, and the panel protection film PPL, when filling a resin in the space 80 between the cover film IC-C, the display panel 10 and the panel protection film PPL, and the waterproof tape 70, the resin may not be effectively filled in the space 80 due to the step.

In addition, when attaching the cover film IC-C to the inner portion of the cut pad area PDA as in the related art, the cover film IC-C, the display panel 10, and the panel protection film PPL may not have a same cut surface, which may cause wrinkles, etc. of the cover film IC-C.

In an embodiment of the present disclosure, when the cover film IC-C having a width greater than that of the pad area PDA is attached and then cut so that the cover film IC-C, the display panel 10, and the panel protection film PPL have a same cut surface CL, the waterproof performance of the electronic device including the display device may be improved, and the attachment quality of the cover film IC-C may be improved.

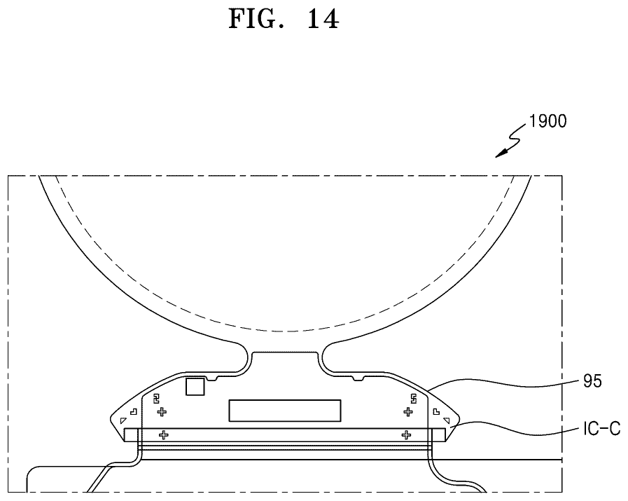

FIG. 14 is a plan view schematically illustrating another example of a display device according to an embodiment of the present disclosure.

Referring to FIG. 14, a display device 1900 according to an embodiment of the present disclosure may be, for example, a smart watch. As described with reference to and illustrated in FIGS. 1 to 13, in the display device 1900, the cover film IC-C having a width greater than a pad area may be attached, and then the cover film IC-C, a display panel, and a panel protection film may be cut along the cutting line 95, so that the cover film IC-C, the display panel, and the panel protection film may have the same cut surface.

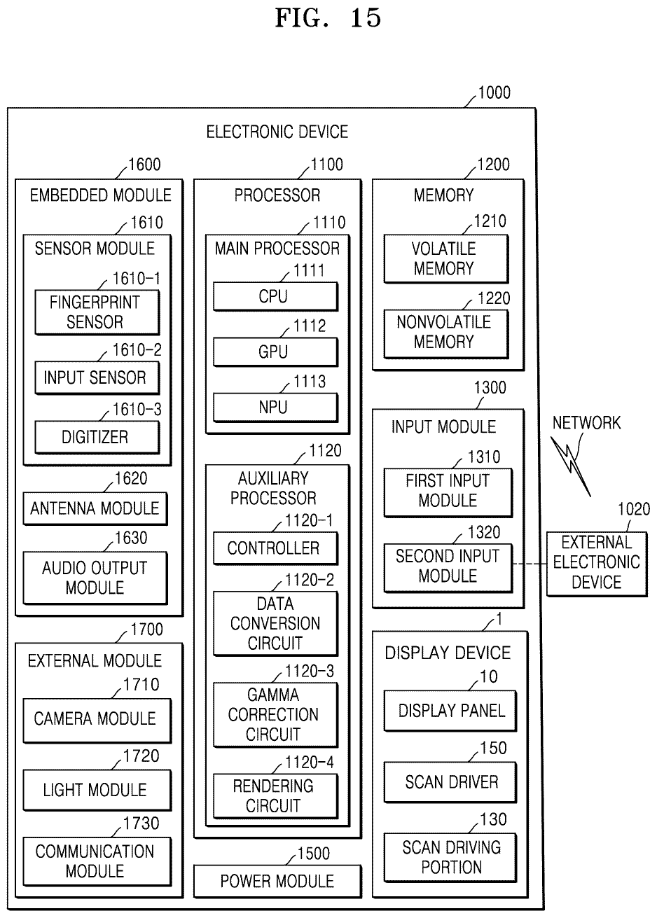

FIG. 15 is a block diagram schematically illustrating an example of an electronic device including a display device, according to embodiments of the present disclosure.

Referring to FIG. 15, an embodiment of an electronic device 1000 outputs various information through the display device 1 within an operating system. The display device 1 may be a display device illustrated in and described with reference to FIGS. 1 to 14. When a processor 1100 executes an application stored in a memory 1200, the display device 1 provides application information to a user through the display panel 10.

The processor 1100 obtains an external input through an input module 1300 or a sensor module 1610 and executes an application corresponding to the external input. For example, when a user selects a camera icon displayed on the display panel 10, the processor 1100 obtains a user input through an input sensor 1610-2 and activates a camera module 1710. The processor 1100 transmits image data corresponding to a photographed image obtained through the camera module 1710 to the display device 1. The display device 1 may display an image corresponding to the photographed image through the display panel 10.

As another example, when personal information authentication is performed on the display device 1, a fingerprint sensor 1610-1 obtains input fingerprint information as input data. The processor 1100 compares input data obtained through the fingerprint sensor 1610-1 with authentication data stored in the memory 1200 and executes an application based on a comparison result. The display device 1 may display information executed according to the logic of the application through the display panel 10.

As another example, when a music streaming icon displayed on the display device 1 is selected, the processor 1100 obtains a user input through the input sensor 1610-2 and activates a music streaming application stored in the memory 1200. When a music execution command is input in a music streaming application, the processor 1100 activates an audio output module 1630 to provide the user with audio information corresponding to the music execution command.

Above, the operation of the electronic device 1000 is briefly described. Below, the configuration of the electronic device 1000 is described in detail. Some of components of the electronic device 1000 described below may be integrated and provided as a single component, and a single component may be separated and provided as two or more components.

Referring to FIG. 15, an embodiment of the electronic device 1000 may communicate with an external electronic device 1020 through a network (e.g., a short-range wireless communication network or a long-range wireless communication network). According to an embodiment, the electronic device 1000 may include the processor 1100, the memory 1200, the input module 1300, the display device 1, a power module 1500, a built-in module 1600, and an external module 1700. According to an embodiment, the electronic device 1000 may have at least one of the above-described components omitted, or one or more other components added. In an embodiment, some of the components described above (e.g., the sensor module 1610, an antenna module 1620, or the audio output module 1630) may be integrated into another component (e.g., the display device 1).

The processor 1100 may execute software to control at least one other component (e.g., a hardware or software component) of the electronic device 1000 connected to the processor 1100 and perform various data processing or operations. According to an embodiment, as at least a portion of data processing or calculation, the processor 1100 may store commands or data received from another component (e.g., the input module 1300, the sensor module 1610, or a communication module 1730) in a volatile memory 1210, process commands or data stored in the volatile memory 1210, and store resulting data in a non-volatile memory 1220.

The processor 1100 may include a main processor 1110 and an auxiliary processor 1120. The main processor 1110 may include at least one selected from a central processing unit (CPU) 1111 or an application processor (AP). The main processor 1110 may further include at least one selected from a graphic processing unit (GPU) 1110-2, a communication processor (CP), and an image signal processor (ISP). The main processor 1110 may further include a neural network processing unit (NPU) 1110-3. An NPU is a processor specialized in processing artificial intelligence models, and artificial intelligence models may be generated through machine learning. An artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the examples described above. An artificial intelligence model may additionally or alternatively include a software structure in addition to a hardware structure. At least two selected from the processing units and processors described above may be implemented as a single integrated configuration (e.g., a single chip) or each may be implemented as an independent configuration (e.g., multiple chips).

The auxiliary processor 1120 may include a controller 1120-1. The controller 1120-1 may include an interface conversion circuit and a timing control circuit. The controller 1120-1 receives an image signal from the main processor 1110, converts a data format of the image signal to match the interface specifications with the display device 1, and outputs the image data. The controller 1120-1 may output various control signals necessary for driving the display device 1.

The auxiliary processor 1120 may further include the controller 1120-1, a data conversion circuit 1120-2, a gamma correction circuit 1120-3, a rendering circuit 1120-4, etc. The data conversion circuit 1120-2 may receive image data from the controller 1120-1, compensate for the image data such that the image is displayed at a desired brightness based on the characteristics of the electronic device 1000 or the user's settings, or convert the image data to reduce power consumption or compensate for afterimages. The gamma correction circuit 1120-3 may convert image data or a gamma reference voltage, etc. in a way such that the image displayed on the electronic device 1000 has desired gamma characteristics. The rendering circuit 1120-4 may receive image data from the controller 1120-1 and render the image data by taking into consideration a pixel layout of the display panel 10 applied to the electronic device 1000. At least one selected from the data conversion circuit 1120-2, the gamma correction circuit 1120-3, and the rendering circuit 1120-4 may be integrated into another component (e.g., the main processor 1110 or the controller 1120-1). At least one selected from the data conversion circuit 1120-2, the gamma correction circuit 1120-3, and the rendering circuit 1120-4 may be integrated into a data driving portion 130 described below.

The memory 1200 may store various data used by at least one component of the electronic device 1000 (e.g., the processor 1100 or the sensor module 1610) and input data or output data for commands related thereto. The memory 1200 may include at least one of the volatile memory 1210 and the non-volatile memory 1220. The memory 1200 may store at least one program, and the processor 1100 may operate by executing the at least one of the programs.

The input module 1300 may receive commands or data to be used in the components of the electronic device 1000 (e.g., the processor 1100, the sensor module 1610, or the audio output module 1630) from an external source of the electronic device 1000 (e.g., a user or the external electronic device 1020).

The input module 1300 may include a first input module 1310 into which a command or data is input from a user and a second input module 1320 into which a command or data is input from the external electronic device 1020. The first input module 1310 may include a microphone, a mouse, a keyboard, a key (e.g., a button), or a pen (e.g., a passive pen or an active pen). The second input module 1320 may support a designated protocol that may be connected to the external electronic device 1020 in a wired or wireless manner. According to an embodiment, the second input module 1320 may include a high-definition multimedia interface (HDMI), a universal serial bus (USB) interface, a secure card (SD) card interface, or an audio interface. The second input module 1320 may include a connector that may be physically connected to an external electronic device 1020, for example, an HDMI connector, a USB connector, an SD card connector, or an audio connector (e.g., a headphone connector).

The display device 1 provides information visually to the user. The display device 1 may include the display panel 10, a scan driving portion 150, and a data driving portion 130. The display device 1 may further include a window, a chassis, and a bracket to protect the display panel 10.

The display panel 10 may further include a light-emission driver. The light-emission driver outputs an emission control signal to the display panel 10 in response to a control signal received from the controller 1120-1. The light-emission driver may be formed separately from the scan driving portion 150 or may be integrated into the scan driving portion 150.

The scan driving portion 150 receives a control signal from the controller 1120-1 and outputs scan signals to the display panel 10 in response to the control signal. In an embodiment, for example, a control signal generated by the controller 1120-1 and transmitted to the scan driving portion 150 may be a scan input signal for controlling the scan driving portion 150. The scan input signal may be an input signal applied to switching elements included in stages of a scan driver.

The data driving portion 130 receives a control signal from the controller 1120-1, converts image data into analog voltages (e.g., data voltages) in response to the control signal, and then outputs the data voltages to the display panel 10. In an embodiment, for example, a control signal generated from the controller 1120-1 and transmitted to the data driving portion 130 may be a data input signal for controlling the data driving portion 130.

The data driving portion 130 may be integrated into another component (e.g., controller 1120-1). The functions of an interface conversion circuit and a timing control circuit of the controller 1120-1 may be integrated into the data driving portion 130.

The controller 1120-1 may generate a clock signal required to drive the scan driving portion 150. Each stage of the scan driving portion 150 may operate based on a clock signal corresponding to each stage.

The scan driving portion 150 may generate a scan signal based on a scan input signal, a clock signal, and a scan input voltage. A scan signal may be transmitted to a pixel circuit, and a thin-film transistor included in the pixel circuit may be driven based on the scan signal. The scan signal may be transmitted to a gate included in the pixel circuit.

The display device 1 may further include a light-emission driver and a voltage generation circuit, etc. The voltage generation circuit may output various voltages required to drive the display panel 10.

The power module 1500 supplies power to the components of the electronic device 1000. The power module 1500 may generate a gate driving voltage (e.g., gate high voltage, gate low voltage) required to drive the scan driving portion 150.

In an embodiment, for example, the power module 1500 may refer to a power generation unit, a power supply, etc. In an embodiment, for example, the power module 1500 may include a battery that charges a power voltage. The battery may include a non-rechargeable primary battery, a rechargeable secondary battery, or a fuel cell.

In an embodiment, for example, the power module 1500 may include a power management integrated circuit (PMIC). The PMIC provides optimized power for each of the modules described above and those described below.

In an embodiment, for example, the power module 1500 may include a wireless power transmitter/receiver member electrically connected to a battery. The wireless power transmitter/receiver may include a plurality of coil-shaped antenna radiators.

The electronic device 1000 may further include the built-in module 1600 and the external module 1700. The built-in module 1600 may include the sensor module 1610, the antenna module 1620, and the audio output module 1630. The external module 1700 may include the camera module 1710, the light module 1720, and the communication module 1730.

The sensor module 1610 may detect an input by the user's body or input by a pen among the first input modules 1310 and generate an electric signal or data value corresponding to the input. The sensor module 1610 may include at least one selected from the fingerprint sensor 1610-1, the input sensor 1610-2, and the digitizer 1610-3.

The fingerprint sensor 1610-1 may generate a data value corresponding to the user's fingerprint. The fingerprint sensor 1610-1 may include either an optical or capacitive fingerprint sensor.

The input sensor 1610-2 may generate data values corresponding to coordinate information of an input by the user's body or an input by a pen. The input sensor 1610-2 generates a data value based on a change in electrostatic capacitance due to an input. The input sensor 1610-2 may detect input by a passive pen or transmit and receive data to or from an active pen.

The input sensor 1610-2 may also measure biosignals such as blood pressure, moisture, or body fat. In an embodiment, for example, when a user touches a part of his or her body to a sensor layer or sensing panel and does not move for a certain period of time, the input sensor 1610-2 may detect a biosignal based on a change in the electric field caused by the part of his or her body and output information desired by the user to the display device 1.

The digitizer 1610-3 may generate data values corresponding to coordinate information input by the pen. The digitizer 1610-3 generates a data value based on a change in the electromagnetics due to the input. The digitizer 1610-3 may detect an input from a passive pen or transmit and receive data to or from an active pen.

At least one selected from the fingerprint sensor 1610-1, the input sensor 1610-2, and the digitizer 1610-3 may be implemented as a sensor layer formed on the display panel 10 through a continuous process. The fingerprint sensor 1610-1, the input sensor 1610-2, and the digitizer 1610-3 may be disposed above the display panel 10, and any one of the fingerprint sensor 1610-1, the input sensor 1610-2, and the digitizer 1610-3, for example, the digitizer 1610-3, may be disposed also below the display panel 10.

At least two selected from the fingerprint sensor 1610-1, the input sensor 1610-2, and the digitizer 1610-3 may be formed to be integrated into a single sensing panel through a same process. When integrated into a single sensing panel, the sensing panel may be arranged between the display panel 10 and a window arranged above the display panel 10. According to an embodiment, the sensing panel may be arranged on a window, and the location of the sensing panel is not particularly limited.

At least one of the fingerprint sensor 1610-1, the input sensor 1610-2, and the digitizer 1610-3 may be built into the display panel 10. That is, through a process of forming elements (e.g., light-emitting elements, transistors, etc.) included in the display panel 10, at least one of the fingerprint sensor 1610-1, the input sensor 1610-2, and the digitizer 1610-3 may be formed simultaneously.

In addition, the sensor module 1610 may generate an electrical signal or data value corresponding to an internal or external state of the electronic device 1000. The sensor module 1610 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting signals or power to or receiving signals or power from the outside. According to an embodiment, the communication module 1730 may transmit a signal to an external electronic device or receive a signal from an external electronic device through an antenna suitable for a communication method. The antenna pattern of the antenna module 1620 may be integrated into one component of the display device 1 (e.g., the display panel 10) or the input sensor 1610-2.

The audio output module 1630 is a device for outputting audio signals to the outside of the electronic device 1000, and may include, for example, a speaker used for general purposes such as multimedia playback or recording playback, and a receiver used exclusively for phone reception. According to an embodiment, the receiver may be formed integrally with or separately from the speaker. A sound output pattern of the audio output module 1630 may be integrated into the display device 1.

The camera module 1710 may capture still images and videos. According to an embodiment, the camera module 1710 may include one or more lenses, image sensors, or image signal processors. The camera module 1710 may further include an infrared camera capable of measuring the presence or absence of a user, the user's location, the user's line of sight, etc.

The light module 1720 may provide light. The light module 1720 may include a light-emitting diode or a xenon lamp. The light module 1720 may operate in conjunction with the camera module 1710 or independently.

The communication module 1730 may support establishment of a wired or wireless communication channel between the electronic device 1000 and the external electronic device 1020, and performance of communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may communicate with the external electronic device 1020 via a short-range communication network such as Bluetooth, WiFi direct, or infrared data association (IrDA), or a long-range communication network such as a cellular network, the Internet, or a computer network (e.g., a LAN or wide area network (WAN)). The various types of communication module 1730 described above may be implemented as a single chip or as separate chips.

The input module 1300, the sensor module 1610, the camera module 1710, etc. may be used to control the operation of the display device 1 in conjunction with the processor 1100.

The processor 1100 outputs a command or data to the display device 1, the audio output module 1630, the camera module 1710, or the light module 1720 based on input data received from the input module 1300. In an embodiment, for example, the processor 1100 may generate image data in response to input data applied through a mouse or an active pen, etc., and output the image data to the display device 1, or generate command data in response to input data and output the command data to the camera module 1710 or the light module 1720. When no input data is received from the input module 1300 for a certain period of time, the processor 1100 may switch an operation mode of the electronic device 1000 to a low power mode or a sleep mode to reduce power consumption of the electronic device 1000.

The processor 1100 outputs a command or data to the display device 1, the audio output module 1630, the camera module 1710, or the light module 1720 based on sensing data received from the sensor module 1610. In an embodiment, for example, the processor 1100 may compare authentication data authorized by the fingerprint sensor 1610-1 with authentication data stored in the memory 1200, and then execute an application based on a comparison result. The processor 1100 may execute a command or output corresponding image data to the display device 1 based on sensing data detected by the input sensor 1610-2 or the digitizer 1610-3. When a temperature sensor is included in the sensor module 1610, the processor 1100 may receive temperature data on the temperature measured from the sensor module 1610 and perform brightness correction, etc. on image data based on temperature data.

The processor 1100 may receive measurement data on the presence or absence of the user, the user's location, the user's line of sight, etc. from the camera module 1710. The processor 1100 may further perform brightness correction, etc. on image data based on the measurement data. In an embodiment, for example, the processor 1100 that determines the presence or absence of the user through an input from the camera module 1710 may output image data with brightness corrected through the data conversion circuit 1120-2 or the gamma correction circuit 1120-3 to the display device 1.

Some of the above components may be connected to each other via a communication method between peripheral devices, such as a bus, general purpose input/output (GPIO), serial peripheral interface (SPI), mobile industry processor interface (MIPI), or ultra path interconnect (UPI) link, to exchange signals (e.g., commands or data) with each other. The processor 1100 may communicate with the display device 1 through a mutually agreed upon interface, and for example, may use any one of the above-described communication methods, and is not limited to the above-described communication methods.

The electronic device 1000 according to various embodiments disclosed in the present disclosure may be a device of various forms. The electronic device 1000 may include, for example, a portable communication device (e.g., a smartphone), a computer device, a portable multimedia device, a portable medical device, a camera, a wearable device, or a home appliance device. The electronic device 1000 according to an embodiment of in the present disclosure is not limited to the devices described above.

In an embodiment, the display device 1 may include the display panel 10 and the scan driving portion 150. The controller 1120-1 may generate a scan input signal necessary for driving the scan driving portion 150. The power module may generate a scan input voltage required to drive the scan driving portion 150 under the control by a processor or the controller 1120-1. In an embodiment, for example, a scan input voltage may be a gate drive voltage.

The display panel 10 may be divided into the display area DA where pixel circuits are arranged and a peripheral area PA around the display area DA. As described above, an area where an image is displayed may be the display area DA, and an area outside the display area DA where no image is displayed may be the peripheral area PA. The peripheral area PA may also be referred to as the non-display area NDA.

The scan driving portion 150 may be arranged in the peripheral area PA and may receive a scan input signal from the controller 1120-1 and a scan input voltage from a power module. The scan driving portion 150 may generate a scan signal or output a scan signal based on a scan input signal and/or a scan input voltage. The scan signal may be transmitted from the scan driving portion 150 to a pixel circuit.

In an embodiment, the scan driving portion 150 may include at least one capacitor. At least one capacitor may include one electrode and another electrode. In an embodiment, for example, one electrode may be a signal line through which a scan input signal or a scan input voltage is transmitted. In an embodiment, for example, one electrode may be at least a portion of a signal line through which at least one of a scan input signal or a scan input voltage is transmitted. A signal line, for example, may be a wire through which scan input voltages are transmitted.

In an embodiment, for example, another electrode may overlap the one electrode. Another electrode may overlap a signal line through which at least one of a scan input signal or a scan input voltage is transmitted. In an embodiment, for example, another electrode may overlap at least a portion of a signal line through which at least one of a scan input signal or a scan input voltage is transmitted.

In an embodiment, the peripheral area PA may include a wiring arrangement area in which wires are arranged, and a circuit arrangement area in which at least one transistor is arranged between the display area DA and the wiring arrangement area. In an embodiment, for example, at least one capacitor may be arranged in the wiring arrangement area. At least one capacitor may be arranged in the wiring arrangement area.

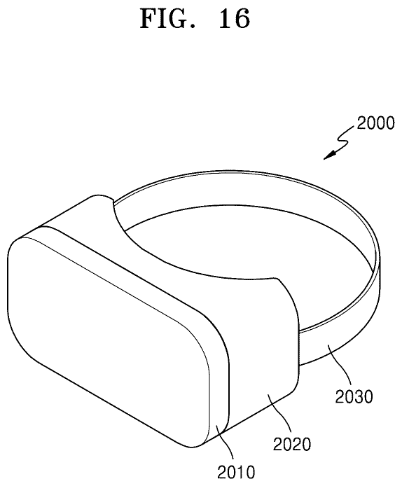

FIG. 16 is a perspective view schematically illustrating an example of an electronic device including a display device, according to embodiments of the present disclosure.

Referring to FIG. 16, an embodiment of an electronic device 2000 including a display device may be implemented as, for example, a head mounted display (HMD). The electronic device 2000 may include a display portion 2010, a main body portion 2020, and a mounting portion 2030.

In an embodiment, for example, the display portion 2010 may include the display device according to the embodiments described above FIGS. 1 to 14 to implement a screen. The main body portion 2020 may include a controller, a touch sensor, or an acoustic sensor that applies a scan signal and a data signal to the display portion 2010. The electronic device 2000 may be mounted on a user via the mounting portion 2030.

However, this is an example and the electronic device 2000 is not limited to the head mounted display. In an embodiment, for example, the electronic device may be another type of electronic device including a display device such as a Virtual Reality (VR) device, a mobile phone, a smart phone, a table computer, a digital television, a three-dimensional (3D) television (TV), a personal computer, a home appliance, a laptop computer, a personal digital assistant (PDA), a portable multimedia player (PMP), a digital camera, a music player, a portable game console, a navigation system, etc.

According to the embodiments of the present disclosure, when attaching a cover film to a pad area and a flexible circuit board, the cover film having a greater width than the width of the pad area is attached, and then, in an LFC process, the cover film, the display panel, and the panel protection film are cut simultaneously to effectively prevent a step difference in cut surfaces of the cover film, the display panel, and the panel protection film, thereby improving the waterproof performance of an electronic device including a display device and improving the attachment quality of the cover film.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic device comprising a display device, wherein the display device comprises:
a display panel including a display area, a pad area located at one side of the display area, and a bending area between the display area and the pad area;
a panel protection film attached to a lower portion of the display panel;
a flexible circuit board attached to the pad area; and
a cover film attached to the pad area and the flexible circuit board,
wherein the pad area overlaps the display area in a state where the bending area is bent, and
a side surface of the cover film, a side surface of the display panel, and a side surface of the panel protection film are on a same cut surface.

2. The electronic device of claim 1, wherein the cover film comprises at least one selected from an insulation film, a conductive film, or a step film.

3. The electronic device of claim 1, wherein the cut surface is located on a side of the pad area.

4. The electronic device of claim 1, wherein the pad area includes a marker, and
the cover film exposes the marker.

5. The electronic device of claim 1, wherein an inspection wire is positioned in the pad area, and a distance between the inspection wire and the cut surface is in a range of about 80 μm to about 150 μm.

6. The electronic device of claim 1, further comprising a cover layer positioned below the panel protection film.

7. The electronic device of claim 6, wherein the cover layer comprises at least one of a cushion layer and a metal plate.

8. The electronic device of claim 7, wherein the metal plate comprises a material having an elastic modulus of about 60 GPa or greater at a room temperature.

9. The electronic device of claim 1, further comprising an upper protective film attached to an upper portion of the display panel.

10. The electronic device of claim 1, wherein the display panel comprises an organic light-emitting diode.

11. A method of manufacturing an electronic device including a display device, the method comprising:
performing a preparation operation of preparing a display panel including a display area, a pad area, and a bending area between the display area and the pad area;
performing a panel protection film attachment operation of attaching a panel protection film to a lower surface of the display panel;
performing a flexible circuit board attachment operation of attaching a flexible circuit board to the pad area;
performing a cover film attachment operation of attaching a cover film to the pad area and the flexible circuit board;
performing a cutting operation of simultaneously cutting the cover film, the display panel and the panel protection film; and
performing a bending operation of bending the display panel,
wherein a side surface of the cover film, a side surface of the display panel, and a side surface of the panel protection film collective define a same cut surface.

12. The method of claim 11, wherein, in the performing the cover film attachment operation, the cover film having a greater width than a width of the pad area is attached.

13. The method of claim 12, wherein a difference in length between one end of the cover film and one end of the pad area is in a range of about 200 μm to about 500 μm.

14. The method of claim 11, wherein, in the performing the cutting operation, the cutting comprises laser cutting.

15. The method of claim 11, further comprising, after the performing the cutting operation, attaching an upper protective film on the display panel.

16. The method of claim 11, further comprising, after the performing the cutting operation, forming a cover layer below the panel protection film.

17. The method of claim 11, wherein the cover film comprises at least one selected from an insulation film, a conductive film, or a step film.

18. The method of claim 11, wherein an inspection wire is positioned in the pad area, and a distance between the inspection wire and the cut surface is in a range of about 80 μm to about 150 μm.

19. The method of claim 11, wherein the pad area includes a marker, and the cover film exposes the marker.

20. An electronic device comprising:
a memory which stores a program;
a processor which operates by executing the program;
a display device which receives data from the processor and provides visual information; and
a power module which supplies power to the display device,
wherein the display device comprises:
a display panel including a display area, a pad area located at one side of the display area, and a bending area between the display area and the pad area;
a panel protection film attached to a lower portion of the display panel;
a flexible circuit board attached to the pad area; and
a cover film attached to the pad area and the flexible circuit board,
wherein a side surface of the cover film, a side surface of the display panel, and a side surface of the panel protection film are on a same cut surface.
